(19) United States
(12) Patent Application Publication
(10) Pub. No.: US 2025/0029656 A1
(43) Pub. Date: Jan. 23, 2025

(54) MEMORY DEVICE INCLUDING VARIABLE SERIAL RESISTIVE ELEMENT HAVING VOLTAGE DIVIDING EFFECT AND OPERATING METHOD THEREOF

(71) Applicant: Samsung Electronics Co., Ltd., Suwon-si (KR)

(72) Inventors: Yumin KIM, Suwon-si (KR); Seyun KIM, Suwon-si (KR); Garam PARK, Suwon-si (KR); Hyunjae SONG, Suwon-si (KR); Seungyeul YANG, Suwon-si (KR); Seungdam HYUN, Suwon-si (KR)

(73) Assignee: Samsung Electronics Co., Ltd., Suwon-si (KR)

(21) Appl. No.: 18/774,249

(22) Filed: Jul. 16, 2024

(30) Foreign Application Priority Data
Jul. 18, 2023 (KR) 10-2023-0093341

(51) Int. Cl. G11C 13/00

(52) U.S. Cl. CPC G11C 13/0069; G11C 13/004; G11C 13/0097

(57) ABSTRACT

A memory device including a variable serial resistive element having a voltage dividing effect and an operating method thereof are disclosed. The memory device includes a memory unit, a variable serial resistive element connected to the memory unit, a controller connected to the variable serial resistive element and configured to control a resistance of the variable serial resistive element, and a power source connected to the variable serial resistive element. The operating method of the memory device includes maintaining a resistance of a serial resistive element connected to a memory element as a first resistance during a first operation of the memory element and maintaining the resistance of the serial resistive element as a second resistance during a second operation of the memory element, wherein the serial resistive element includes a variable resistive element.

### CROSS-REFERENCE TO RELATED APPLICATION

This application is based on and claims priority under 35 U.S.C. § 119 to Korean Patent Application No. 10-2023-0093341, filed on Jul. 18, 2023, in the Korean Intellectual Property Office, the disclosure of which is incorporated by reference herein in its entirety.

### BACKGROUND

### 1. Field

The disclosure relates to memory devices and/or operating methods thereof, and more specifically, to memory devices including a variable serial resistive element having a voltage dividing effect and operating methods thereof.

### 2. Description of the Related Art

An incremental step pulse programming (ISPP) method has been used to improve the characteristics of a memory element. However, in this method, an operation time and power consumption may increase, and it may be difficult to respond to various commands when a resistance state of a memory element suddenly changes.

Accordingly, a method of preventing over-SET and improving the durability of a memory element has been introduced. In this method, a serial resistive element is used. In the method, a portion of a voltage is also applied across a serial resistive element at the moment when the resistance of the memory element is changed from high resistance to low resistance.

### SUMMARY

Some example embodiments provide memory devices with improved durability in response to sudden changes in a resistance state.

Some example embodiments provide memory devices with reduced operation time and power consumption.

Some example embodiments provide operating methods of such memory devices.

Additional aspects will be set forth in part in the following description and in part will be apparent from the description, or may be learned by practice of the presented example embodiments of the disclosure.

According to an aspect of the disclosure, a memory device includes a memory unit, a variable serial resistive element connected to the memory unit, a controller connected to the variable serial resistive element and configured to control a resistance of the variable serial resistive element, and a power source connected to the variable serial resistive element.

The memory unit may include a resistive memory element. The memory unit may include a resistive variable element or a resistance change layer. The memory unit may include a vertical NAND (VNAND) memory.

According to an example embodiment, a method of operating a memory device, the method includes maintaining a resistance of a serial resistive element connected to a memory element as a first resistance during a first operation of the memory element and maintaining the resistance of the serial resistive element as a second resistance during a second operation of the memory element, wherein the serial resistive element includes a variable resistive element.

In some example embodiments, the first resistance and the second resistance may be maintained at a same value.

In some example embodiments, the first and second operations may be repeated, and during the repetition of the first and second operations, the first resistance may be gradually increased and the second resistance may be maintained at 0 according to a resistance state of the memory element.

In some example embodiments, the first and second operations may be repeated, and during the repetition of the first and second operations, the second resistance may be gradually increased and the first resistance may be maintained at 0 according to a resistance state of the memory element.

In some example embodiments, the first and second operations may be repeated, and during the repetition of the first and second operations, the first resistance may be gradually increased and the second resistance may remain greater than 0 and less than the first resistance according to the resistance state of the memory element. The second resistance may remain constant while the first and second operations are repeated.

In some example embodiments, the first and second operations are repeated, and during the repetition of the first and second operations, the second resistance may be gradually increased and the first resistance may remain greater than 0 and less than the second resistance according to a resistance state of the memory element. The first resistance may remain constant while the first and second operations are repeated.

In some example embodiments, as an operation cycle of the memory element including the first and second operations is repeated, the resistance state of the memory element is configured to converge from one of a high-resistance state and a low-resistance state to the other of the high-resistance state and the low-resistance state.

In some example embodiments, one of the first operation and the second operation may be a data recording operation and the other of the first and second operations may be a data erasing operation. One of the first operation and the second operation may be a set operation and the other of the first and second operations may be a reset operation.

In some example embodiments, the resistance of the serial resistive element may be controlled by a controller connected to the serial resistive element.

In some example embodiments, the method may further include performing a third operation between the first operation and the second operation. The third operation may include a read operation.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a block diagram showing a memory device including a variable series resistance component having a voltage dividing effect according to an example embodiment;

FIG. 2 is a conceptual diagram showing an operation of a memory device including a variable serial resistive element having a voltage dividing effect according to an example embodiment, and also displays a time chart showing changes in an operating voltage and variable serial resistive element of the memory device over time;

FIG. 3 is a diagram showing an operation of a memory device including a variable serial resistive element having a voltage dividing effect according to an example embodiment, and also displays a time chart showing an operation method to improve a resistance state of the memory device when the resistance state converges from a high resistance state (HRS) to a low resistance state (LRS) as the operation cycle of the memory device is repeated;

FIG. 4 is a time chart showing a case when a serial resistance of a reset operation in the operation method of FIG. 3 is greater than 0;

FIG. 5 is a time chart showing an operation method of a memory device when the memory device operates in a case opposite to that of FIG. 3;

FIG. 6 is a time chart showing a case when the serial resistance of the set operation in the operation method of FIG. 5 is greater than 0;

FIG. 7 is an example circuitry of the variable serial resistive element 40; and

FIG. 8 is a flow chart explaining how a controller adjusts a resistance of a variable serial resistive element based on a resistive state of the memory unit.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, some example embodiments are merely described below, by referring to the figures, to explain some aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

Hereinafter, memory devices including a variable serial resistive element having a voltage dividing effect according to some example embodiments and methods of operating the same will be described in detail with reference to the accompanying drawings. In this process, the thicknesses of layers or regions shown in the drawings may be somewhat exaggerated for clarity of description.

The example embodiments of the disclosure are capable of various modifications and may be embodied in many different forms. Additionally, in the layer structure described below, when an element or layer is referred to as being “on” or “above” another element or layer, the element or layer may be directly on another element or layer or intervening elements or layers.

The singular forms include the plural forms unless the context clearly indicates otherwise. Additionally, when a part “comprises” or “includes” an element in the specification, unless otherwise defined, it is not excluding other elements but may further include other elements.

The use of the term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the terms “units” or “ . . . modules” denote units or modules that process at least one function or operation, and may be realized by hardware, software, or a combination of hardware and software.

Also, the connections of lines and connection members between constituent elements depicted in the drawings are examples of functional connection and/or physical or circuitry connections, and thus, in practical devices, may be expressed as replaceable or additional functional connections, physical connections, or circuitry connections.

All examples or example terms are simply used to explain in detail the technical scope of the disclosure, and thus, the scope of the disclosure is not limited by the examples or the example terms as long as it is not defined by the claims.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

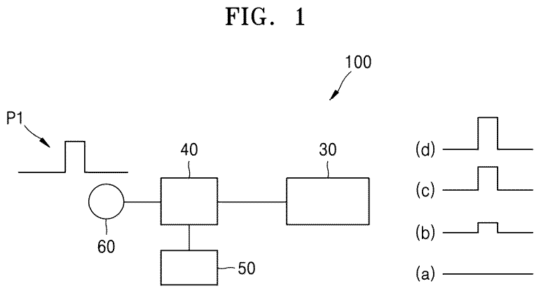

FIG. 1 is a block diagram showing a memory device 100 including a variable serial resistive element having a voltage dividing effect according to an example embodiment.

Referring to FIG. 1, the memory device 100 includes a memory unit 30, a variable serial resistive element 40 connected to the memory unit 30, a controller 50 connected to the variable serial resistive element 40, and a power source 60 configured to supply an operating voltage to the memory unit 30 via the variable serial resistive element 40. The power source 60 may be connected to the variable serial resistive element 40. In some example embodiments, a pulse voltage may be supplied to the memory unit 30 from the power source 60. In some example embodiments, the memory unit 30 may include a memory element that writes or reads data using a resistance change characteristic. In some example embodiments, the memory element may include a plurality of memory cells. In some example embodiments, the memory unit 30 may be a memory element that records data using a resistance change element or a resistance change layer having at least two different resistance states. As an example, the memory unit 30 may be a resistive RAM and may include vertical NAND (VNAND) including a vertical resistance change layer, but is not limited thereto. A unit memory cell of the resistive RAM or a unit memory cell of the VNAND may include a transistor and a resistance change layer. In some example embodiments, the transistor may be a field effect transistor (FET).

In some example embodiments, the variable serial resistive element 40 may be or include a variable resistor connected in series to the memory unit 30. The resistance change of the variable serial resistive element 40 may be controlled by the controller 50. In some example embodiment, although not specifically illustrate in the drawings, the controller may be further configured to monitor the resistance state of the memory unit 30 or may be configured to communicate with a separate monitoring unit that is configured to monitor the resistance state of the memory unit 30.

A resistance of the variable serial resistive element 40 may be maintained at 0 or substantially 0 by the controller 50 or may have a resistance value greater than 0. The resistance of the variable serial resistive element 40 may be arbitrarily changed between 0 and a set maximum resistance by the controller 50. In some example embodiments, the controller 50 may change the resistance of the variable serial resistive element 40 in an electrical manner, but is not limited thereto.

In FIG. 1, a voltage pulse P1 represents an operating voltage supplied from the power source 60 to the memory unit 30. In some example embodiments, when the voltage pulse P1 is supplied from the power source 60, a resistance of the variable serial resistive element 40 according to an operating state (e.g., a resistance state) of the memory unit 30 may vary as illustrated in (a) to (d) on the right. In (a), there is no resistance pulse, which indicates that the resistance of the variable serial resistive element 40 is 0.

When the resistance state of the memory unit 30 is in a high resistance state, an operating voltage may be applied to the memory unit 30, but when the resistance state of the memory unit 30 is changed to a low resistance state from a high resistance state, a portion of the operating voltage may be applied to the variable serial resistive element 40, and thus an excessive operating voltage may be blocked or prevented from being applied to the memory unit 30. In this respect, the variable serial resistive element 40 may be considered to have a voltage dividing effect.

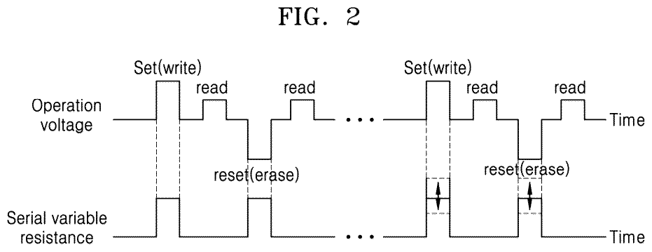

FIG. 2 is a diagram showing the concept of resistance change of the variable serial resistive element 40 when an operating voltage is applied to the memory unit 30. In some example embodiments, the operating voltage may be a voltage applied to measure durability characteristics of the memory unit 30.

Referring to FIG. 2, a set voltage (set), a read voltage (read), a reset voltage (reset), and a read voltage (read) may be sequentially applied to the memory unit 30, and afterwards, the same voltage application process may be repeated. The process of sequentially applying the set voltage, the read voltage, the reset voltage, and the read voltage may be one cycle of an operation of the memory unit 30. The set voltage may be a voltage for writing data to the memory unit 30. The read voltage may be a voltage for reading written data. The reset voltage may be a voltage that erases written data. The operation (process) of applying the set voltage may be expressed as a set operation (process), and the operation (process) of applying the reset voltage may be expressed as a reset operation (process). Also, one of the set operation and the reset operation may be expressed as a first operation, and the other may be expressed as a second operation.

As the operation cycle of the memory unit 30 is repeated, the resistance state of the memory unit 30 may change. For example, it may occur a case in which one of a high resistive state (HRS) and a low resistive state (LRS) of the memory unit 30 may converge to the other state. If this case occurs, the possibility of malfunction of the memory unit 30 increases. If a normal resistance state of the memory unit 30 is maintained, the resistance of the variable serial resistive element 40 may be maintained constant during the set operation and the reset operation of the memory unit 30. However, as described above, when a change in the resistance state of the memory unit 30 occurs, the resistance of the variable serial resistive element 40 may be increased or decreased in a set operation or a reset operation to restore the resistance state. When the resistance state of the memory unit 30 is restored to the normal state due to a change in the resistance of the variable serial resistive element 40, the resistance of the variable serial resistive element 40 may also be maintained as is.

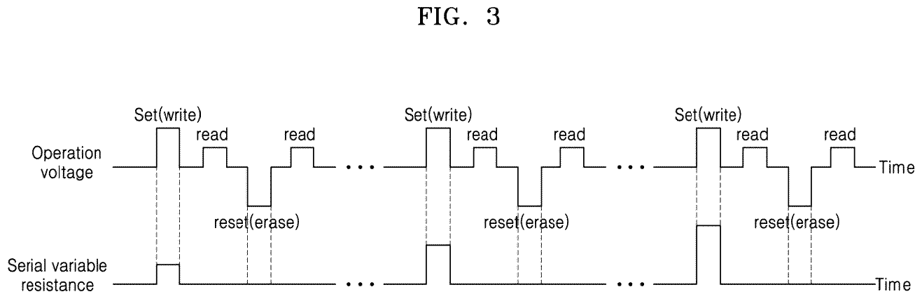

FIG. 3 is a diagram showing the change in resistance of the variable serial resistive element 40 to restore the resistance state of the memory unit 30 when the high resistance state of the memory unit 30 converges to a low resistance state as the operation cycle of the memory unit 30 is repeated.

Referring to FIG. 3, when the high resistance state of the memory unit 30 converges to a low resistance state, the resistance of the variable serial resistive element 40 in a set operation may be controlled to gradually increase as the cycle is repeated. Also, the resistance of the variable serial resistive element 40 in the reset operation may be maintained at 0. When the resistance state of the memory unit 30 is restored to normal through this operation, the resistance of the variable serial resistive element 40 in the set operation and the reset operation may be kept the same or substantially the same.

A time of changing a resistance of the variable serial resistive element 40 in a set operation or a reset operation may be a time when the high or low resistance state of the memory unit 30 is changed from a set reference resistance state in the previous operation cycle. That is, if the resistance state of the memory unit 30 in the previous operation cycle is different from the reference resistance state, the resistance of the variable serial resistive element 40 may be greater or less than in the previous operation cycle.

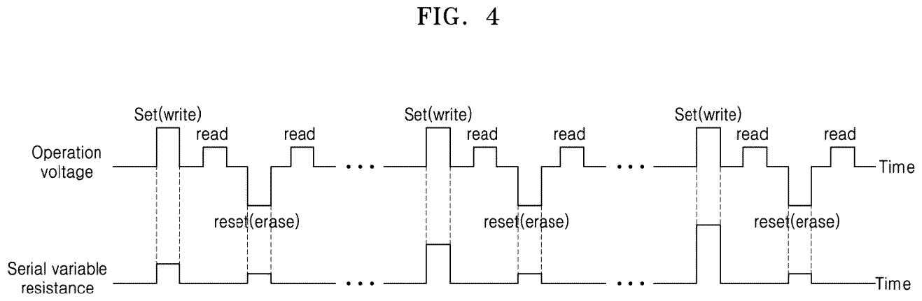

In the case of FIG. 3, the resistance of the variable serial resistive element 40 may not be maintained at 0 during the reset operation of the memory unit 30. For example, as shown in FIG. 4, the resistance of the variable serial resistive element 40 in the reset operation may be greater than 0, but the magnitude of the resistance in the reset operation may be less than the resistance of the variable serial resistive element 40 in the set operation. For example, the magnitude of the resistance in the reset operation may be less than a minimum resistance of the variable serial resistive element 40 in a set operation. The resistance of the variable serial resistive element 40 in the reset operation may be less than the resistance of the variable serial resistive element 40 in the set operation and may be constant.

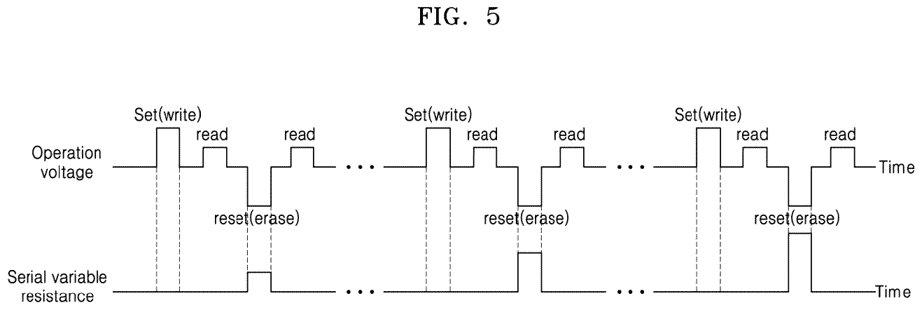

FIG. 5 shows the resistance change of the variable serial resistive element 40 in a set operation and a reset operation when the resistance state of the memory unit 30 is opposite to that of FIG. 3, that is, when the low resistance state (LRS) of the memory unit 30 changes to a high resistance state (HRS) as the operation cycle of the memory unit 30 is repeated.

Referring to FIG. 5, as the operation cycle of the memory unit 30 is repeated, the resistance of the variable serial resistive element 40 in the reset operation may be controlled to gradually increase. On the other hand, the resistance of the variable serial resistive element 40 in the set operation may be maintained at 0. As the resistance state of the memory unit 30 is restored to normal, the resistance of the variable serial resistive element 40 in the set operation and the reset operation of the memory unit 30 may be the same or substantially the same.

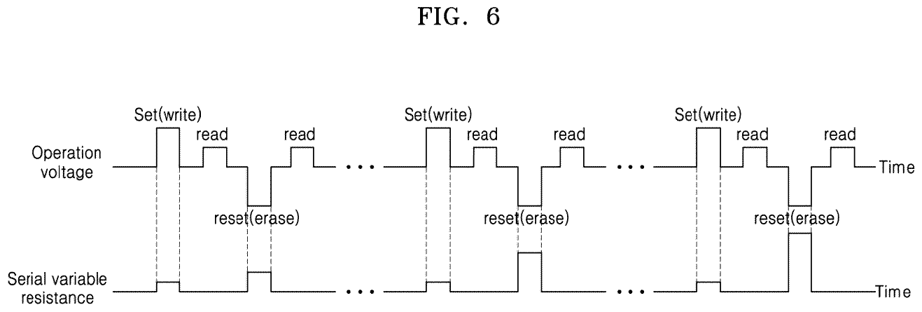

FIG. 6 shows a case when the resistance of the variable serial resistive element 40 in the set operation of the memory unit 30 in the case of FIG. 5 is not 0.

Referring to FIG. 6, the resistance of the variable serial resistive element 40 in the set operation is greater than 0 but may be less than the resistance of the variable serial resistive element 40 in the reset operation. For example, the resistance of the variable serial resistive element 40 in the set operation may be less than the minimum resistance of the variable serial resistive element 40 in the reset operation. The resistance of the variable serial resistive element 40 in the set operation may be less than the resistance of the variable serial resistive element 40 in the reset operation and may be constant.

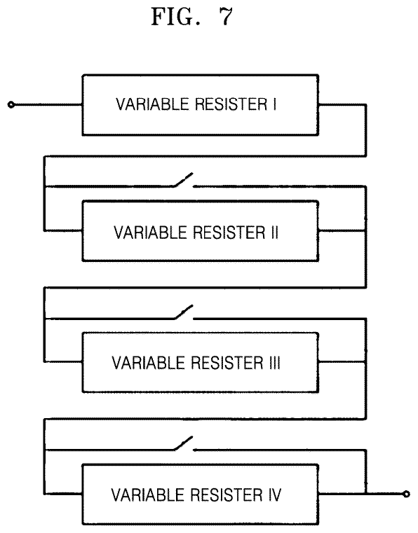

FIG. 7 is an example circuitry of the variable serial resistive element 40.

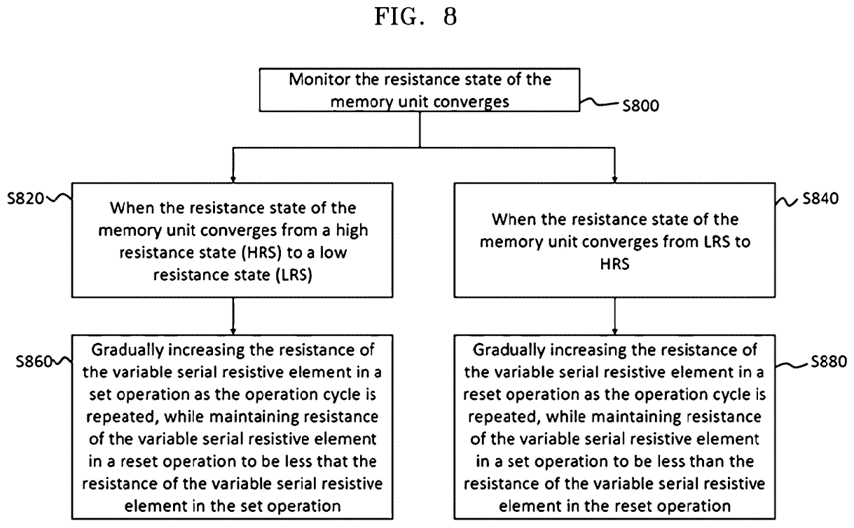

FIG. 8 is a flow chart explaining how the controller 50 adjusts the resistance of the variable serial resistive element 40 based on the resistive state of the memory unit 30 to mitigate or prevent an application of an overvoltage to the operation of the memory unit.

In operation S800, the controller 50 (or a separate monitoring apparatus) may monitor the resistance state of the memory unit 30. In some example embodiment, a separate monitoring apparatus may monitor the resistance state of the memory unit 30 and provide the monitored results to the controller 50.

In operation S820, it may be determined that the resistance state of the memory unit 30 converges from a high resistance state (HRS) to a low resistance state (LRS). Then, the controller 50 may gradually increase the resistance of the variable serial resistive element 40 in a set operation as the operation cycle is repeated, while maintaining resistance of the variable serial resistive element in a reset operation to be less that the resistance of the variable serial resistive element in the set operation (operation S860).

In operation S840, it may be determined that the resistance state of the memory unit 30 converges from a low resistance state (LRS) to a high resistance state (HRS). Then, the controller 50 may gradually increase the resistance of the variable serial resistive element 40 in a reset operation as the operation cycle is repeated, while maintaining resistance of the variable serial resistive element in a set operation to be less that the resistance of the variable serial resistive element in the reset operation (operation S880).

The disclosed memory device includes a variable serial resistive element. A resistance of the variable serial resistive element is controlled by a controller and the variable serial resistive element is connected in series to a memory unit. Because the resistance of the variable serial resistive element may be controlled according to a resistance state of the memory unit, even if a resistance state of the memory unit is suddenly changed during an operation of the memory unit, the application of an overvoltage to the operation of the memory unit may be mitigated or prevented. Accordingly, the durability of the memory unit may be improved. Additionally, a pulse width of a voltage applied during an operation of the memory unit may be maintained greater than that of a voltage applied to an existing ISPP method, thereby reducing the operation time and power consumption of the memory unit.

Various elements (e.g., controller, power source, variable serial resistive element) disclosed in the present disclosure as black boxes may be implemented as processing circuitry such as hardware including logic circuits or a combination of hardware and software such as a processor executing software. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A memory device comprising:
a memory unit;
a variable serial resistive element connected to the memory unit;
a controller connected to the variable serial resistive element and configured to control a resistance of the variable serial resistive element; and
a power source connected to the variable serial resistive element.

2. The memory device of claim 1, wherein the memory unit comprises a resistive memory element.

3. The memory device of claim 1, wherein the memory unit comprises one of a resistive variable element and a resistance change layer.

4. The memory device of claim 1, wherein the memory unit comprises a vertical NAND (VNAND) memory.

5. An operating method of a memory device, the operating method comprising:
maintaining a resistance of a serial resistive element connected to a memory element as a first resistance during a first operation of the memory element; and
maintaining the resistance of the serial resistive element as a second resistance during a second operation of the memory element,
wherein the serial resistive element comprises a variable resistive element.

6. The operating method of claim 5, wherein the first resistance and the second resistance are maintained at a same value.

7. The operating method of claim 5, wherein the first and second operations are repeated, and
during the repetition of the first and second operations, the first resistance is gradually increased, and the second resistance is maintained at 0 according to a resistance state of the memory element.

8. The operating method of claim 5, wherein the first and second operations are repeated, and
during the repetition of the first and second operations, the second resistance is gradually increased, and the first resistance is maintained at 0 according to a resistance state of the memory element.

9. The operating method of claim 5, wherein the first and second operations are repeated, and
during the repetition of the first and second operations, the first resistance is gradually increased, and the second resistance remains greater than 0 and less than the first resistance according to a resistance state of the memory element.

10. The operating method of claim 9, wherein the second resistance remains constant during the repetition of the first and second operations.

11. The operating method of claim 5, wherein the first and second operations are repeated, and
during the repetition of the first and second operations, the second resistance is gradually increased, and the first resistance remains greater than 0 and less than the second resistance according to a resistance state of the memory element.

12. The operating method of claim 11, wherein the first resistance remains constant during the repetition of the first and second operations.

13. The operating method of claim 5, wherein one of the first and second operations is a data recording operation and the other of the first and second operations is a data erasing operation.

14. The operating method of claim 5, wherein one of the first and second operations is a set operation and the other of the first and second operations is a reset operation.

15. The operating method of claim 5, wherein the resistance of the serial resistive element is controlled by a controller connected to the serial resistive element.

16. The operating method of claim 5, further comprising:
performing a third operation between the first operation and the second operation.

17. The operating method of claim 16, wherein the third operation includes a read operation.
